(19) United States
(12) Patent Application Publication
(10) Pub. No.: US 2026/0337762 A1
(43) Pub. Date: Oct. 29, 2026

(54) CHEMICAL VAPOR DEPOSITION OF SILICON NITRIDE USING A REMOTE PLASMA

(71) Applicant: Lam Research Corporation, Fremont, CA (US)

(72) Inventors: Shane TANG, Camas, WA (US); Gopinath BHIMARASETTI, Portland, OR (US); Andrew J. MCKERROW, Lake Oswego, OR (US)

(21) Appl. No.: 19/119,730

(22) PCT Filed: Oct. 27, 2023
(86) PCT No.: PCT/US2023/078079

§ 371 Date: Apr. 9, 2025

Related U.S. Application Data
(60) Provisional application No. 63/382,638, filed on Nov. 7, 2022.

(51) Int. Cl. C23C 16/34; C23C 16/04; C23C 16/44; C23C 16/455

(52) U.S. Cl. CPC C23C 16/345; C23C 16/045; C23C 16/4412; C23C 16/45536; C23C 16/45553

(57) ABSTRACT

Examples are disclosed that relate to low-damaging deposition of silicon nitride films using chemical layer deposition (CVD). One example provides a method (300) for forming a silicon nitride film on a substrate in a processing chamber by chemical vapor deposition. The method comprises introducing (302) a nitrogen-containing precursor into a remote plasma formed in a remote plasma chamber of a processing tool. The method further comprises forming (308) radical nitrogen species in the remote plasma. The method further comprises flowing (312) an oxygen-free silicon-containing precursor into a processing chamber of the processing tool. The method further comprises, while flowing the oxygen-free silicon-containing precursor, introducing (316) the radical nitrogen species from the remote plasma chamber into the processing chamber. The method further comprises reacting the oxygen-free silicon-containing precursor with the radical nitrogen species to form the silicon nitride film on the substrate.

### BACKGROUND

Semiconductor fabrication processes may involve many steps of material deposition, patterning, and removal to form integrated circuits on substrates. For example, silicon nitride may be deposited and patterned to form many different structures in integrated circuits. Atomic layer deposition (ALD) may be used to form highly conformal films of silicon nitride. ALD forms a film in one or more individual film layers by sequentially adsorbing a precursor to a substrate and then reacting the adsorbed precursor to form a film layer.

### SUMMARY

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. Furthermore, the claimed subject matter is not limited to implementations that solve any or all disadvantages noted in any part of this disclosure.

Examples are disclosed that relate to low-damaging chemical vapor deposition (CVD) of silicon nitride films using a remote plasma. One example provides a method for forming a silicon nitride film on a substrate in a processing chamber by chemical vapor deposition. The method comprises introducing a nitrogen-containing precursor into a remote plasma formed in a remote plasma chamber of a processing tool. The method further comprises forming radical nitrogen species in the remote plasma. The method further comprises flowing an oxygen-free silicon-containing precursor into a processing chamber of the processing tool. The method further comprises, while flowing the oxygen-free silicon-containing precursor, introducing the radical nitrogen species from the remote plasma chamber into the processing chamber. The method further comprises reacting the oxygen-free silicon-containing precursor with the radical nitrogen species to form the silicon nitride film on the substrate.

In some such examples, forming the silicon nitride film comprises forming a conformal silicon nitride film.

In some such examples, flowing the oxygen-free silicon-containing precursor additionally or alternatively comprises flowing a silane-based precursor.

In some such examples, forming the silicon nitride film additionally or alternatively comprises forming the silicon nitride film on one or more of an amorphous silicon mandrel or an amorphous carbon mandrel.

In some such examples, forming the silicon nitride film additionally or alternatively comprises forming the silicon nitride film in one or more gaps on the substrate.

In some such examples, the method additionally or alternatively comprises performing atomic layer deposition to deposit additional silicon nitride onto the silicon nitride film.

In some such examples, forming nitrogen radical species additionally or alternatively comprises using a radiofrequency power within a range of 300 to 2000 watts to form the remote plasma.

In some such examples, the method additionally or alternatively comprises controlling a pressure of the processing chamber to within a range of 2 to 8 torr while forming the silicon nitride film.

In some such examples, introducing the nitrogen-containing precursor into the remote plasma additionally or alternatively comprises introducing one or more of nitrogen, nitrogen/hydrogen, ammonia, hydrazine, or an amine into the remote plasma.

Another example provides a method of forming a silicon nitride film on a substrate in a processing chamber of a chemical vapor deposition (CVD) tool. The method comprises introducing a nitrogen-containing precursor into a remote plasma formed in a remote plasma chamber of the CVD tool. The method further comprises forming radical nitrogen species in the remote plasma. The method further comprises introducing an oxygen-free silicon-containing precursor into the processing chamber of the CVD tool. The method further comprises introducing the radical nitrogen species from the remote plasma chamber into the processing chamber. The method further comprises reacting the oxygen-free silicon-containing precursor with the radical nitrogen species to form the silicon nitride film on the substrate. The method further comprises performing atomic layer deposition to form one or more additional layers of silicon nitride on the silicon nitride film.

In some such examples, forming the silicon nitride film on the substrate comprises forming the silicon nitride film on one or more mandrels.

In some such examples, the one or more mandrels comprise amorphous silicon.

In some such examples, the one or more mandrels additionally or alternatively comprise amorphous carbon.

In some such examples, forming the silicon nitride film on the substrate additionally or alternatively comprises forming the silicon nitride film in one or more gaps on the substrate.

In some such examples, introducing the oxygen-free silicon-containing precursor into the processing chamber additionally or alternatively comprises introducing a silane-based precursor into the processing chamber.

In some such examples, introducing the nitrogen-containing precursor into the remote plasma additionally or alternatively comprises introducing one or more of nitrogen, nitrogen/hydrogen, ammonia, hydrazine, or an amine into the remote plasma.

Another example provides a chemical vapor deposition (CVD) tool. The CVD tool comprises a processing chamber and a remote plasma chamber. The CVD tool further comprises a radiofrequency power source configured to form a plasma in the remote plasma chamber. The CVD tool further comprises a nitrogen precursor source comprising a nitrogen-containing precursor. The CVD tool further comprises an oxygen-free silicon-containing precursor source comprising an oxygen-free silicon-containing precursor. The CVD tool further comprises flow control hardware configured to introduce the nitrogen-containing precursor into the remote plasma chamber and introduce the oxygen-free silicon-containing precursor into the processing chamber. The CVD tool further comprises a controller configured to operate the flow control hardware to introduce the nitrogen-containing precursor into the remote plasma chamber. The controller is further configured to operate the radiofrequency power source to form a plasma from the nitrogen-containing precursor, the plasma comprising radical nitrogen species. The controller is further configured to operate the flow control hardware to flow the oxygen-free silicon-containing precursor into the processing chamber. The controller is further configured to operate the flow control hardware to introduce the radical nitrogen species from the remote plasma chamber into the processing chamber to react with the oxygen-free silicon-containing precursor and form a silicon nitride film on a substrate.

In some such examples, the nitrogen-containing precursor source comprises one or more of nitrogen, nitrogen/hydrogen, ammonia, hydrazine, or an amine.

In some such examples, the CVD tool additionally or alternatively comprises a hydrogen-containing precursor source comprising hydrogen gas, and the controller is configured to operate the radiofrequency power source to form the plasma from the nitrogen-containing precursor and the hydrogen gas.

In some such examples, the CVD tool additionally or alternatively comprises an exhaust system, and the controller is configured to operate the exhaust system and the flow control hardware to generate a pressure within the processing chamber within a range of 2 to 8 torr while forming the silicon nitride film on the substrate.

### BRIEF DESCRIPTION OF THE DRAWINGS

FIGS. 1A-1C schematically show structures formed in an example atomic layer deposition (ALD) of a silicon nitride film onto amorphous silicon mandrels, and a subsequent etch step that results in material loss.

FIGS. 2A-2B schematically show swelling of example amorphous carbon mandrels resulting from an ALD deposition of a silicon nitride film.

FIG. 3 shows a flow diagram illustrating an example method for performing chemical vapor deposition (CVD) of a silicon nitride film using radical nitrogen species formed in a remote plasma.

FIGS. 4A-4C schematically show structures formed in an example CVD deposition of a silicon nitride film on a substrate comprising mandrels.

FIGS. 5A-5C schematically show structures formed in an example CVD deposition of a silicon nitride film in gaps on a substrate.

FIG. 6 shows a schematic view of an example CVD tool configured to deposit silicon nitride films using radical nitrogen species generated in a remote plasma.

FIG. 7 shows a block diagram of an example computing system.

### DETAILED DESCRIPTION

The term “alkyl amine” may generally represent compounds comprising a nitrogen with 1 to 3 alkyl substituents and 0 to 2 hydrogen (H) substituents. Alkyl amines comprise primary, secondary, tertiary, and cyclic amines. Examples of alkyl amines include methylamine, dimethylamine, trimethylamine, and piperidine.

The term “aspect ratio” may generally represent a ratio between a depth of a feature and an average width of the feature.

The term “atomic layer deposition” (ALD) may generally represent a process in which a film is formed on a substrate in one or more individual layers by sequentially adsorbing a precursor to the substrate and reacting the adsorbed precursor to form a film layer. Examples of ALD processes comprise plasma-enhanced ALD (PEALD) and thermal ALD (TALD). PEALD utilizes a plasma of a reactive gas to facilitate a chemical conversion of a precursor adsorbed to a substrate to a film on the substrate. TALD utilizes heat to facilitate a chemical conversion of a precursor adsorbed to a substrate to a film on the substrate, The terms “growth” and “deposition”, and variants thereof, also may be used to refer to film formation.

The term “ALD cycle” may generally represent a sequence of processes used to form a single layer of a film on a substrate in an ALD process.

The term “chemical vapor deposition” (CVD) may generally represent a process in which a solid phase film is formed on a substrate by directing a continuous flow of one or more precursor gases over the substrate surface under conditions configured to cause the chemical conversion of the precursor gases to the film. The term “plasma-enhanced chemical-vapor deposition” (PECVD) may generally represent a CVD process in which a plasma is used to facilitate the chemical conversion of one or more precursor gases to a solid phase film on a substrate.

The term “CVD tool” may generally represent a machine comprising a processing chamber and other hardware configured to perform CVD.

The term “conformal film” may generally represent a film comprising a thickness that varies by 10% or less. A conformal film may comprise a thickness at a first location that is 90% to 110% of the thickness of the film at a second location.

The term “gap” may generally represent a recess formed in a substrate surface.

The term “mandrel” may generally represent a raised structure in a patterning process with sidewalls that define locations of spacers. Mandrels may be formed from any polycrystalline silicon, amorphous silicon, and amorphous carbon, as examples.

The term “nitrogen-containing precursor” may generally represent any material that can be introduced into a plasma to form radical nitrogen species which can react with one or more other precursors to form a silicon nitride film. Examples of suitable nitrogen-containing precursors may include nitrogen (N₂), ammonia (NH₃), hydrazine (N₂H₄), and amines such as diamines and alkyl amines. Examples of nitrogen-containing precursors further may include mixtures of gases. Example mixtures of gases include nitrogen/hydrogen and ammonia/hydrogen.

The term “oxygen-free silicon-containing precursor” may generally represent any molecule that lacks oxygen and can be introduced into a processing chamber in a gas phase to react with nitrogen radical species to form a silicon-containing nitride film on the substrate. An example silicon-containing nitride is silicon nitride (Si₃N₄). Example oxygen-free silicon-containing precursors for forming silicon-containing nitride films may comprise materials having the general structure:

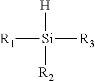

where R₁, R₂ and R₃ may be the same or different substituents, and may include silanes, amines, halides, hydrogen, or organic groups, such as alkylamines, alkyl, alkenyl, alkynyl, and aromatic groups.

More specific example oxygen-free silicon-containing precursors include silane-based precursors (silane and polysilanes ((H₃Si—(SiH₂)ₙ—SiH₃), where n≥0)). Example oxygen-free silicon-containing precursors also include trisilylamine (TSA). In further examples, the oxygen-free silicon-containing precursor may be an aminosilane, such as bisdiethylaminosilane, diisopropylaminosilane, bis(t-butylamino) silane (BTBAS), di-sec-butylaminosilane, or tris(dimethylamino)silane (3DMAS). Aminosilane precursors may have the general formula: Hₓ—Si—(NR)_{y}, where x=1-3, x+y=4, and R is a substituted or unsubstituted alkyl, substituted or unsubstituted alkenyl, substituted or unsubstituted alkynyl, substituted or unsubstituted aromatic group, or hydride group.

The term “patterning process” may generally represent a process that is used to generate topography on a substrate.

The term “plasma” may generally represent a gas comprising cations and free electrons. A plasma may be used to generate reactive chemical species from a precursor molecule introduced into the plasma. The term “in-situ plasma” may generally represent a plasma to which a substrate is directly exposed during a process. The term “remote plasma” may generally represent a plasma that is located remote from a substrate being processed.

The term “processing chamber” may generally represent an enclosure in which chemical and/or physical processes are performed on substrates. The pressure, temperature and atmospheric composition within a processing chamber are controllable to perform chemical and/or physical processes.

The terms “purge” and variants thereof may generally represent processes in which unwanted species are removed from a processing chamber.

The term “radical” may generally represent a chemical species with an unpaired electron.

The term “radical nitrogen species” may generally represent nitrogen-containing atomic or molecular with an unpaired electron. Examples include N, NH, NH₂, and NH₃ radicals.

The term “radiofrequency (RF) power source” may generally a power source configured to provide RF power to electrodes to form a capacitively coupled plasma, or a coil to form an inductively coupled plasma.

The term “remote plasma generator” may generally represent one or more components of a processing tool configured to form a remote plasma. A remote plasma generator includes an RF power source and a remote plasma chamber in which the remote plasma is formed.

The term “silane-based precursor” may generally represent silane and polysilanes ((H₃Si—(SiH₂)ₙ—SiH₃), where n≥0). Example polysilanes include disilane, trisilane, and tetrasilane.

The term “spacer” may generally represent a structure formed in a patterning process that define a spacing between features to be formed in a later processing step.

The term “substrate” may generally represent any object on which a film can be deposited.

The term “substrate support” may generally represent any structure for supporting a substrate in a processing chamber. Examples include pedestals, electrostatic chuck pedestals, and showerhead pedestals used for backside deposition processes.

As mentioned above, silicon nitride is used to form many structures in integrated circuit. Conformal films of silicon nitride can be deposited by plasma-enhanced ALD (PEALD). In a silicon nitride PEALD cycle, a silicon-containing precursor gas is introduced into a processing chamber. The silicon-containing precursor gas adsorbs to a substrate in the processing chamber. Excess film precursor is purged from the processing chamber. Next, a nitrogen-containing precursor is introduced into the processing chamber. A plasma is then formed by application of radiofrequency power to electrodes within the processing chamber. The plasma forms reactive species such as radical nitrogen species. The radical nitrogen species react with the adsorbed silicon-containing precursor to form a layer of silicon nitride. A highly conformal film of a target thickness can be grown using one or more PEALD cycles.

However, deposition of silicon nitride by PEALD may be unsuitable for some applications. For example, some substrates are susceptible to plasma damage. Examples of such substrates include amorphous silicon, amorphous carbon, and chalcogenides. Film precursors for silicon nitride PEALD may include halosilanes such as dichlorosilane or diiodosilane. Radical halogen species formed from halosilanes in a plasma may etch some substrate materials. Further, the PEALD process may utilize a relatively high power in-situ plasma comprising nitrogen and hydrogen. Such conditions can result in nitridation of a substrate.

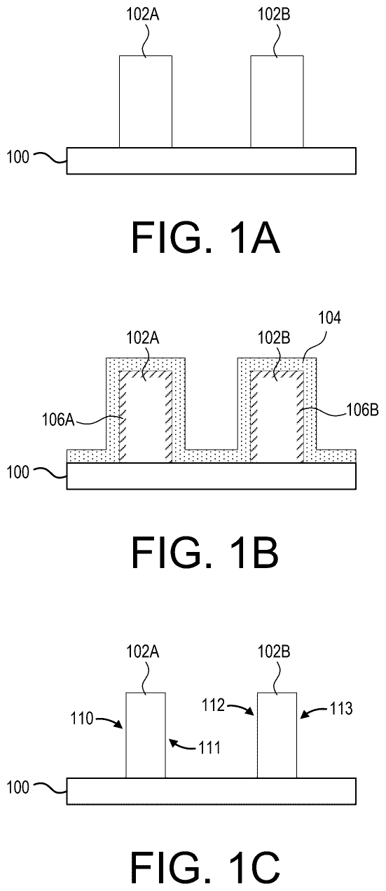

Nitridation of a substrate may result in unwanted material loss during a subsequent etch step. This is illustrated in FIGS. 1A-1C. FIG. 1A shows a substrate 100 comprising silicon mandrels 102A, 102B. Silicon mandrels 102A, 102B comprise amorphous-silicon (a-Si). FIG. 1B shows a silicon nitride film 104 deposited on silicon mandrels 102A, 102B using PEALD. As the ALD process uses a direct plasma to facilitate the growth of silicon nitride film 104, reactive species formed in the direct plasma impinge on silicon mandrels 102A, 102B. This causes nitridation of the α-Si. The nitridation forms nitride layers 106A, 106B on silicon mandrels 102A, 102B, respectively.

FIG. 1C shows substrate 100 following an etching process to remove silicon nitride film 104. The etching process also removes at least some of nitride layers 106A, 106B. This results in material loss from sidewalls 110, 111 of silicon mandrel 102A and sidewalls 112, 113 of silicon mandrel 102B. Due to the material loss, the silicon mandrels 102A, 102B shown in FIG. 1C are thinner compared to those shown in FIG. 1A. Material loss in mandrels may affect pattern transfer.

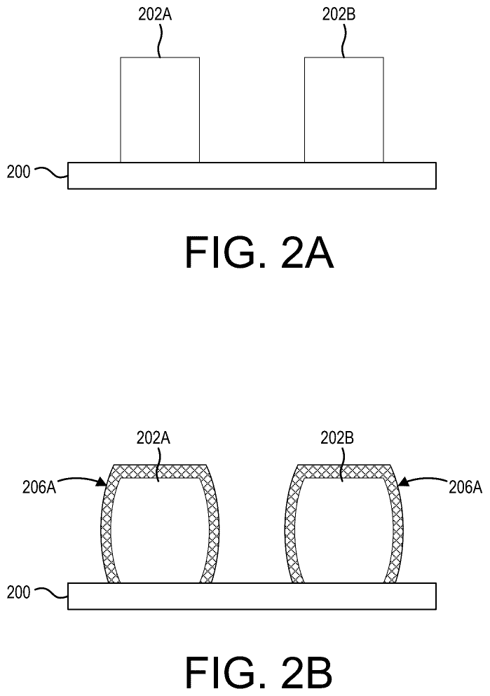

Use of a direct plasma during deposition of silicon nitride by PEALD also may cause swelling of carbon substrate features. This is illustrated in FIGS. 2A-2B. FIG. 2A shows a substrate 200 comprising carbon mandrels 202A, 202B. Carbon mandrels 202A, 202B comprise amorphous carbon. FIG. 2B shows a silicon nitride layer 206A, 206B deposited onto carbon mandrels 202A, 202B, respectively. The silicon nitride layer 206A, 206B is deposited using PEALD. Due to use of a direct plasma and high power during PEALD, energetic species in the plasma impinge on carbon mandrels 202A, 202B and react with the carbon. This causes the mandrels to swell. As a result, carbon mandrels 202A, 202B of FIG. 2B may be unsuitable for patterning applications.

Energetic species in a direct plasma also may cause halogenation and etching of chalcogenide substrate materials, where a halogen-containing precursor is used. Advanced memory architectures, such as magnetoresitive random-access memory (MRAM) and phase-change random-access memory (PRAM) may utilize chalcogenides, such as selenium and tellurium. However, such materials may be sensitive to water vapor, oxygen, other gases, and/or plasmas. For example, plasma species used in the deposition of silicon nitride by PEALD may react with the chalcogenide to form H₂Te or H₂Se. As H₂Te and H₂Se have relatively low boiling points, generation of H₂Te or H₂Se may cause etching.

Accordingly, examples are disclosed that relate to forming a silicon nitride film by CVD using radical nitrogen species formed in a remote plasma. As described in more detail below, the disclosed examples may provide for suitably conformal film growth to serve as a protective layer prior to performing a conformal atomic layer deposition of silicon nitride. Further, the disclosed examples may be used in place of a PEALD silicon nitride deposition process where a relatively thin silicon nitride film is desired. Briefly, a nitrogen-containing precursor is introduced into a remote plasma formed in a remote plasma chamber. Radical nitrogen species are formed in the remote plasma. The radical nitrogen species are introduced into a processing chamber comprising a substrate. An oxygen-free silicon-containing precursor is introduced into the processing chamber. The radical nitrogen species react with the oxygen-free silicon-containing precursor to form a silicon nitride film on the substrate. By using radical species formed in a remote plasma to activate the oxygen-free silicon-containing precursor, the disclosed examples may help avoid damage from a direct plasma, such as nitridation, swelling, halogenation, and etching. In some examples, the use of a relatively higher pressure and/or a relatively lower power compared to other CVD processes may provide a suitably low impact energy to the substrate surface. Further, use of a silicon-containing precursor that is oxygen-free and/or halogen-free for the CVD deposition may help to avoid oxidation and/or etching of substrate materials.

Silicon nitride film deposition by CVD according to the present disclosure may be performed with precursors that are relatively less expensive compared to other methods such as PEALD. For example, silane-based precursors such as silane and polysilanes may be used. These materials may be less expensive than other silicon-containing film precursors such as trisilylamine (TSA). Thus, the disclosed examples may provide cost savings compared to formation of a nitride film by PEALD. The disclosed examples also may help to avoid the above-described problems with substrate damage from nitridation, swelling, halogenation, and/or etching.

As mentioned above, a silicon nitride film deposited by CVD according to the present disclosure may be used as a standalone film in place of a PEALD silicon nitride film. This is due to the disclosed CVD deposition methods forming relatively conformal silicon nitride films. Some such conformal CVD-deposited silicon nitride films may comprise a thickness that is 50 Å or less. Other conformal CVD-deposited silicon nitride films according to the present disclosure may comprise thicknesses greater than 50 Å.

In other examples, a silicon nitride film deposited by CVD according to the present disclosure may be used as an interfacial layer. For example, a silicon nitride film deposited by CVD according to the present disclosure may be used to form a protective silicon nitride film on a substrate surface that is vulnerable to damage from PEALD. Then, PEALD may be performed to deposit additional layers of silicon nitride onto the silicon nitride film. The CVD-deposited silicon nitride film thus acts as an interfacial layer between the substrate material and the ALD silicon nitride layers. The conformal nature of the CVD-deposited silicon nitride interfacial layer allows the overall silicon nitride to be similarly conformal as if PEALD alone were used to deposit the silicon nitride film. Further, by first depositing a silicon nitride film according to the examples disclosed herein, substrate damage may be avoided.

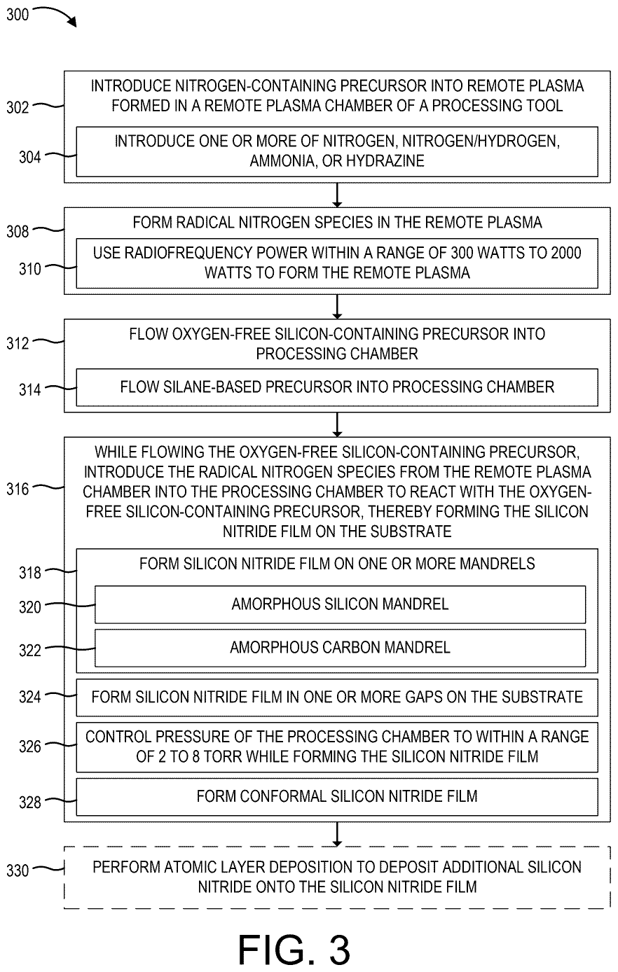

FIG. 3 shows a flow diagram of an example method 300 for forming a silicon nitride film on a substrate. At 302, method 300 comprises introducing a nitrogen-containing precursor into a remote plasma formed in a remote plasma chamber. The nitrogen-containing precursor may comprise any suitable gas that can form radical nitrogen species in a plasma. Examples include nitrogen (N₂), ammonia (NH₃), hydrazine (N₂H₄), and amines such as diamines and alkyl amines. In some examples, introducing the nitrogen-containing precursor at 302 comprises introducing a mixture of nitrogen and hydrogen. In such examples, at 304, method 300 may comprise introducing one or more of nitrogen, nitrogen/hydrogen, ammonia, hydrazine, or an amine into the remote plasma. Hydrogen also can be mixed with ammonia, hydrazine, and other nitrogen-containing precursors. In some examples, an inert gas may be flowed into the remote plasma. Example inert gases comprise helium (He) and argon (Ar).

At 308, method 300 comprises forming radical nitrogen species in the remote plasma. Examples of radical nitrogen species include N radicals, NH radicals, NH₂ radicals, and NH₃ radicals. In some examples, the radical nitrogen species may be formed by generating an inductively coupled plasma. In other examples, the radical nitrogen species may be formed by generating a capacitively coupled plasma. In further examples, a microwave plasma may be used. Any suitable radiofrequency (RF) power may be used to form the plasma. In some examples, at 310, method 300 comprises using a radiofrequency power within a range of 300 to 2000 watts (W) to form the remote plasma. In other examples, RF powers outside this range may be used.

Continuing, method 300 further comprises, at 312, flowing an oxygen-free silicon-containing precursor into a processing chamber. Examples of oxygen-free silicon-containing precursors may comprise materials having the general structure:

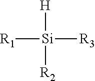

where R₁, R₂ and R₃ may be the same or different substituents, and may include silanes, amines, hydrogen, or organic groups, such as alkylamines, alkyl, alkenyl, alkynyl, and aromatic groups.

More specific examples of oxygen-free silicon-containing precursors include silane-based precursors (silane and polysilanes ((H₃Si—(SiH₂)ₙ—SiH₃), where n≥0)), as indicated at 314. Example oxygen-free silicon-containing precursors also include trisilylamine (TSA). In further examples, the oxygen-free silicon-containing precursor may comprise an aminosilane, such as bisdiethylaminosilane, diisopropylaminosilane, bis(t-butylamino)silane (BTBAS), di-sec-butylaminosilane, or tris(dimethylamino)silane (3DMAS). Aminosilane precursors may have the general formula: Hₓ—Si—(NR)_{y}, where x=1-3, x+y=4, and R is a substituted or unsubstituted alkyl, substituted or unsubstituted alkenyl, substituted or unsubstituted alkynyl, substituted or unsubstituted aromatic group, or hydride group.

The use of a silane-based precursor may provide cost savings compared to examples that use more expensive precursors, such as trisilylamine or halosilanes. However, trisilylamine and/or halosilane precursors may be used in other examples.

In some examples, the oxygen-free silicon-containing precursor also is halogen-free. Use of an oxygen-free and halogen-free silicon-containing precursor may help avoid etching. A halogen-containing precursor may be used when halide etching is less of a concern.

In some examples, an inert gas is flowed with the oxygen-free silicon-containing precursor into the processing chamber as a carrier gas. Examples include nitrogen, helium, and argon.

Method 300 further comprises, at 316, while flowing the oxygen-free silicon-containing precursor, introducing the radical nitrogen species from the remote plasma chamber into the processing chamber. This allows the radical nitrogen species to react with the oxygen-free silicon-containing precursor, thereby forming the silicon nitride film on the substrate.

In some examples, the substrate may comprise one or more mandrels. Thus, in such examples, at 318, the silicon nitride film is formed on the one or more mandrels. In some examples, at 320, the mandrel comprises an amorphous silicon mandrel. In some examples, at 322, the mandrel comprises an amorphous carbon mandrel. In some examples, the silicon nitride film may be deposited over a mandrel to form a protective interfacial layer.

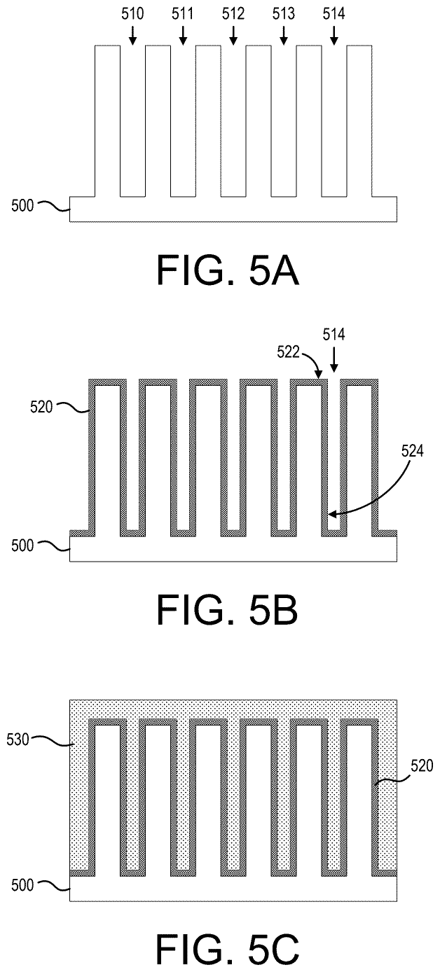

As method 300 uses a remote plasma rather than a direct plasma, the method may help avoid plasma damage, deformation, and/or nitridation to the substrate features. Deposition of silicon nitride over mandrels is discussed in more detail below with reference to FIG. 5.

In other examples, a silicon nitride film may be formed on any other suitable substrate feature using method 300. For example, at 324, the silicon nitride film may be formed in a gap on the substrate. In some such examples, the gap may comprise a relatively high aspect ratio, such as an aspect ratio within a range of 10:1 to 30:1.

Method 300 may utilize any suitable processing conditions for forming the silicon nitride film. In some examples, the substrate is heated during silicon nitride film formation. In some such examples, a substrate may be heated to a temperature within a range of 25 °C to 400 °C. In other examples, the substate may be heated to a temperature above this range.

Further, any suitable pressure may be used during silicon nitride deposition. In some examples, at 326, method 300 comprises controlling the pressure of the processing chamber to within a range of 2 Torr to 8 Torr while forming the silicon nitride film. Such pressures may help to avoid substrate damage from reactive species formed in the remote plasma compared to lower pressures. For example, the use of a relatively higher pressure may decrease a mean free path for radical nitrogen species compared to a relatively lower pressure. A shorter mean free path may decrease an impact rate of radical nitrogen species impinging on the substrate surface. A lower impact rate may help avoid plasma damage.

Additionally, any suitable RF power may be used to form the remote plasma. Examples include RF powers within a range of 300 W to 2000 W. The use of a relatively lower RF power may decrease impact energy of radical nitrogen species on the substrate surface compared to a relatively higher power. A lower impact energy may help avoid plasma damage.

In some examples, processing conditions may be controlled to achieve a desired degree of conformality of the silicon nitride film. For example, the use of a relatively higher pressure together with a relatively lower RF power may help achieve a relatively more conformal silicon nitride film. Thus, at 328, in some examples method 300 comprises forming a conformal silicon nitride film. The conformality of the film may refer to a thickness of a film at the top of the feature compared to a thickness of the film at another location of the feature, such as a bottom or mid-sidewall. In some examples, a thickness of the silicon nitride film near a bottom of a feature is within a range of 90% to 110% of a thickness of the silicon nitride film at a top of the feature. In examples where the silicon nitride film is formed in one or more gaps at 324, conformal deposition may help fill the gaps without forming voids. In other examples, a less conformal silicon nitride film may be formed. A less conformal film may be formed using a relatively higher RF power and/or a relatively lower pressure.

In some examples, the silicon nitride film formed at 316 may be a standalone film. In some examples, a standalone film may comprise a thickness within a range of 3 Å to 50 Å. In other examples, a film may have a thickness outside this range.

In other examples, the silicon nitride film formed at 316 may be an interfacial film. In such examples, at 330, method 300 further comprises performing PEALD to deposit additional silicon nitride onto the silicon nitride film. As discussed above, PEALD of silicon nitride might otherwise cause damage to a substrate in the absence of an interfacial layer. However, the silicon nitride film formed at 316 may protect the substrate from plasma damage during PEALD, as indicated at 330.

In some examples, a silicon nitride film may be formed as part of a patterning application. For example, a silicon nitride film may be deposited over a mandrel to protect the mandrel during a subsequent processing step. Removal of the protective silicon nitride film then allows the mandrels to be used in pattering. In other examples, a silicon nitride film may be deposited to form spacers on sidewalls of a mandrel.

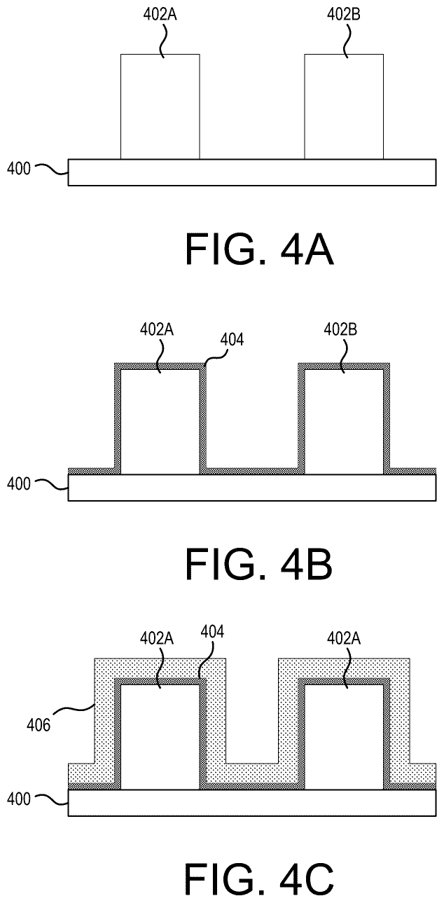

FIGS. 4A-4C schematically show an example silicon nitride film formed on a mandrel using CVD. First, FIG. 4A depicts a substrate 400 comprising mandrels 402A, 402B. Mandrels 402A, 402B may comprise any suitable material, such as carbon or α-Si. Next, FIG. 4B shows a silicon nitride film 404 deposited over mandrels 402A, 402B. Method 300 is an example of a method for forming silicon nitride film 404. Silicon nitride film 404 may comprise any suitable thickness. Examples include thicknesses within a range of 3 Å to 50 Å. In some examples, silicon nitride film 404 may be deposited relatively conformally by using a relatively higher pressure and/or a relatively lower RF power.

By introducing radical nitrogen species from a remote plasma to react with an oxygen-free silicon-containing precursor, plasma damage to mandrels 402A, 402B may be avoided. This may help to prevent material loss and/or swelling. In contrast to FIG. 1B, silicon nitride film 404 may be deposited while avoiding nitridation of mandrels 402A, 402B. In contrast to FIG. 2B, silicon nitride film 404 may be deposited while avoiding swelling of mandrels 402A, 402B. As such, in examples where silicon nitride film 404 is removed by etching, a shape of mandrels 402A, 402B may be preserved. This may help with patterning applications.

FIG. 4C shows an example where additional silicon nitride is deposited conformally using ALD. Additional silicon nitride 406 is deposited over silicon nitride film 404. Deposition of the additional silicon nitride 406 may be performed using any suitable ALD process, such as PEALD or thermal ALD (TALD). In a PEALD cycle, a silicon-containing precursor is introduced into a processing chamber and adsorbs onto substrate 400. The silicon-containing precursor may comprise any suitable precursor that can react to form a silicon nitride film. Examples include silane-based precursors, TSA, alkyl silanes, and halosilanes. Excess silicon-containing precursor is purged from the processing chamber. Then, a nitrogen-containing precursor is introduced. Example nitrogen-containing precursors include nitrogen (N₂), nitrogen/hydrogen, ammonia (NH₃), hydrazine (N₂H₄), and amines such as diamines and alkyl amines. A plasma is struck in the processing chamber to form radical nitrogen species, which react with the adsorbed silicon-containing precursor to form additional silicon nitride 406. In a TALD cycle, thermal energy may be used to facilitate a reaction. One or more ALD cycles may be performed to form a conformal film of silicon nitride of a target thickness.

FIG. 5 schematically shows example structures formed during a CVD process to deposit silicon nitride in gaps on a substrate 500. Substrate 500 may represent an intermediate structure in the fabrication of a trench isolation region, a memory structure, or one or more logic gates. As shown in FIG. 5A, substrate 500 comprises gaps 510, 511, 512, 513, 514. The gaps may comprise any suitable aspect ratio(s). In some examples, the gaps 510, 511, 512, 513, 514 may have an aspect ratio or ratios within a range of 10:1 to 30:1. In other examples, the gaps may have an aspect ratio or ratios outside of this range

Next, FIG. 5B shows a silicon nitride film 520 formed on substrate 500, including in gaps 510, 511, 512, 513, 514. Silicon nitride film 520 is deposited using CVD by reacting an oxygen-free silicon-containing precursor with radical nitrogen species formed in a remote plasma. As described above, conformal deposition of a film in a gap using CVD may be challenging. During CVD, a film growth rate towards the top of a gap may be different from a film growth rate towards the bottom of the gap.

However, the disclosed examples allow a suitably conformal silicon nitride film to be grown by CVD. For example, silicon nitride film 520 may be deposited using method 300 under conditions that favor conformal film growth. As discussed above, relatively higher pressures and relatively lower RF power may favor conformal silicon nitride films. As such, a thickness 522 of silicon nitride film 520 at the top of gap 514 may comprise a similar thickness to thickness 524 at the bottom of gap 514. In some examples, thickness 524 is within a range of 90% to 120% of thickness 522. Further, in some examples, thickness 524 is within a range of 100% to 110% of thickness 522. In some examples, a relatively lower RF power may help achieve a ratio of thickness 524:thickness 522 that is closer to 1:1 compared to examples that use relatively higher RF powers. Conformal deposition of silicon nitride film 520 may help avoid forming reentrant features. Reentrant features narrow along a direction extending from a bottom of a gap toward the top of the gap with respect to the substrate surface. Such reentrant features can close off in a subsequent conformal ALD process.

In some examples, silicon nitride film 520 may comprise a standalone film. In other examples, silicon nitride film 520 may function as an interfacial layer. FIG. 5C shows additional silicon nitride 530 deposited over silicon nitride film 520. In this figure, silicon nitride film 520 is an interfacial layer. In the depicted example, layers of silicon nitride 530 fill gaps 510, 511, 512, 513, 514. Layers of silicon nitride 530 may be deposited using ALD (e.g., PEALD or TALD). As discussed above, PEALD of silicon nitride might otherwise cause damage to a substrate in the absence of an interfacial layer. However, silicon nitride film 520 may protect substrate 500 from plasma damage during PEALD. Further, the conformality of silicon nitride film 520 may allow additional silicon nitride to be deposited by ALD to fill gaps 510, 511, 512, 513, 514 without forming a void (a hollow cavity) in a substrate. A void is a hollow cavity formed in a substrate. Thus, the examples disclosed herein may help fill gaps on a substrate, including high aspect ratio gaps, while avoiding substrate damage.

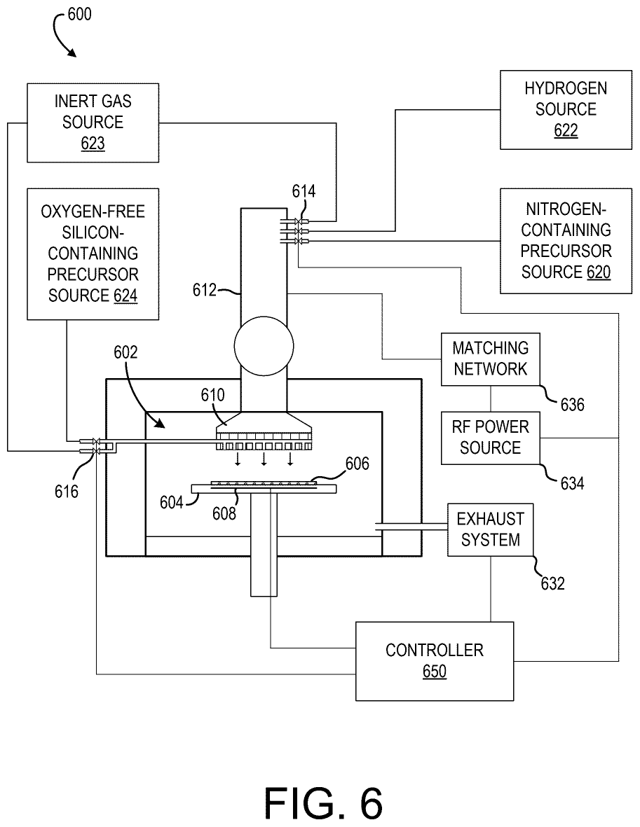

FIG. 6 shows an example CVD tool 600 that may be used to deposit a silicon nitride film on a substrate using a remote plasma. The CVD tool 600 comprises a processing chamber 602 and a substrate support 604 within the processing chamber. Substrate support 604 is configured to support a substrate 606 disposed within processing chamber 602. In some examples, substrate support 604 comprises a substrate heater 608. Substrate support 604 may comprise a pedestal, an electrostatic chuck pedestal, a showerhead pedestal, or any other suitable structure.

CVD tool 600 further comprises a processing gas inlet 610. Processing gas inlet 610 is configured to introduce radical species from a remote plasma chamber 612 into processing chamber 602. In some examples, processing gas inlet 610 may be configured to filter ions and/or radiation that are generated in a remote plasma chamber 612. In some examples, processing gas inlet 610 comprises a showerhead.

CVD tool 600 further comprises flow control hardware 614, 616. Flow control hardware 614 is connected to a nitrogen-containing precursor source 620, an optional hydrogen source 622, and an inert gas source 623. Flow control hardware 616 is connected to an oxygen-free silicon-containing precursor source 624 and inert gas source 623.

Nitrogen-containing precursor source 620 may comprise any suitable nitrogen-containing precursor that is oxygen-free. Examples include nitrogen, ammonia, hydrazine, and amines such as diamines and alkyl amines. Optional hydrogen source 622 comprises hydrogen gas. In other examples, a hydrogen source may be omitted. In some such examples, the nitrogen-containing precursor source may comprise a mixture of a molecule containing nitrogen (such as N₂ or NH₃) and hydrogen (H₂).

Oxygen-free silicon-containing precursor source 624 comprises any suitable oxygen-free silicon-containing precursor. Examples include silane-based precursors, TSA, and aminosilanes, as described above. Use of a silane-based precursor may help to lower costs compared to other precursors such as TSA. Nevertheless, TSA may be used in some examples. In some examples, the oxygen-free silicon-containing precursor may be halogen-free. Inert gas source 623 may comprise any suitable inert gas and may comprise two or more different inert gases that can be flowed separately. Examples include helium, nitrogen, and argon.

Flow control hardware 614 is configured to control the flow of nitrogen-containing precursor from nitrogen-containing precursor source 620 into remote plasma chamber 612. Flow control hardware 614 is further configured to control the flow of hydrogen from optional hydrogen source 622 into remote plasma chamber 612. Flow control hardware 614 is further configured to control the flow of inert gas (e.g., He, Ar) from inert gas source 623 into remote plasma chamber 612. Similarly, flow control hardware 616 is configured to control the flow of oxygen-free silicon-containing precursor into processing chamber 602. Flow control hardware 616 is also configured to control the flow of an inert gas (e.g., He, N₂, Ar) into processing chamber 602. In some examples, an inert gas flowed through flow control hardware 616 is different from an inert gas flowed through flow control hardware 614. Flow control hardware 614, 616 may comprise one or more mass flow controllers and/or valves to control flow rates of gases.

Remote plasma chamber 612 is configured to generate a remote plasma from a nitrogen-containing precursor to generate radical nitrogen species. In some examples, remote plasma chamber 612 may be configured to generate an inductively coupled plasma. In other examples, remote plasma chamber 612 may be configured to generate a capacitively coupled plasma. In further examples, a microwave plasma may be used. Radical nitrogen species may flow into processing chamber 602 through processing gas inlet 610. The radical nitrogen species may facilitate a reaction with the oxygen-free silicon-containing precursor to form a silicon nitride film on substrate 606. By forming radical nitrogen species in a remote plasma chamber, CVD tool 600 may help avoid plasma damage to substrate 606.

CVD tool 600 further comprises an exhaust system 632. Exhaust system 632 is configured to receive gas outflowing from processing chamber 602. In some examples, exhaust system 632 is configured to actively remove gas from processing chamber 602 and/or apply a partial vacuum. Exhaust system 632 may comprise any suitable hardware, including one or pumps.

CVD tool 600 further comprises an RF power source 634 electrically connected to plasma-generating circuitry in remote plasma chamber 612. Examples of plasma-generating circuitry include capacitor plates to generate a capacitively coupled plasma, or a coil to generate an inductively coupled plasma. CVD tool 600 further may include a matching network 636 for impedance matching of RF power source 634. RF power source 634 may be configured to provide suitable frequency and power to form a plasma in remote plasma chamber 612. Examples of suitable frequencies include frequencies in a range from 0.3 MHz to 10 GHz. Examples of suitable powers include powers within a range from 300 W to 2000 W. In some examples, radiofrequency power source 634 is configured to operate at a plurality of different frequencies and/or powers. In other examples, a microwave plasma may be used.

Controller 650 is operatively coupled to substrate heater 608, flow control hardware 614, 616, remote plasma chamber 612, exhaust system 632, and RF power source 634. Controller 650 further may be operatively coupled to any other suitable component of CVD tool 600. Controller 650 is configured to control various functions of CVD tool 600 to deposit a silicon nitride film on a substrate. For example, controller 650 is configured to operate substrate heater 608 to heat a substrate. Controller 650 is also configured to operate flow control hardware 614 to flow a nitrogen-containing precursor at a selected flow rate into remote plasma chamber 612. In some examples, controller 650 also is configured to control flow control hardware 614 to flow hydrogen into remote plasma chamber 612. In some examples, controller 650 also is configured to control flow control hardware 614 to flow an inert gas into remote plasma chamber 612. Furthermore, controller 650 is configured to RF power source 634 to form a remote plasma for introducing radical nitrogen species into processing chamber 602.

Controller 650 also is configured to operate flow control hardware 616 to introduce the oxygen-free silicon-containing precursor into processing chamber 602. Controller 650 also is configured to operate flow control hardware 616 to flow an inert gas with the oxygen-free silicon-containing precursor into processing chamber 602. Thus, controller 650 may cause introduction of oxygen-free silicon-containing precursor and radical nitrogen species into processing chamber 602. The radical nitrogen species react with the oxygen-free silicon-containing precursor to form a silicon nitride film on substrate 606 disposed in the processing chamber 602.

Controller 650 is also configured to operate exhaust system 632 to remove gases from processing chamber 602. Controller 650 is further configured to operate flow control hardware 614, 616 and exhaust system 632 to maintain a selected pressure within processing chamber 602. In some examples, controller 650 is configured to maintain a pressure within a range of 2 to 8 Torr while flowing oxygen-free silicon-containing precursor into processing chamber 602.

Controller 650 further is configured to control processing conditions (e.g., pressure, RF power, gas flow) to control conformality, thickness, and other film characteristics. Controller 650 is further configured to control any other functions of CVD tool 600.

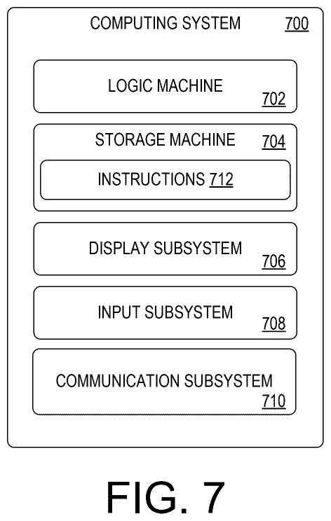

Controller 650 may comprise any suitable computing system. FIG. 7 schematically shows a non-limiting embodiment of a computing system 700 that can enact one or more of the methods and processes described above. Computing system 700 is shown in simplified form. Computing system 700 may take the form of one or more personal computers, workstations, computers integrated with substrate processing tools, and/or network accessible server computers.

Computing system 700 includes a logic machine 702 and a storage machine 704. Computing system 700 may optionally include a display subsystem 706, input subsystem 708, communication subsystem 710, and/or other components not shown in FIG. 7. Controller 650 is an example of computing system 700.

Logic machine 702 includes one or more physical devices configured to execute instructions. For example, the logic machine may be configured to execute instructions that are part of one or more applications, services, programs, routines, libraries, objects, components, data structures, or other logical constructs. Such instructions may be implemented to perform a task, implement a data type, transform the state of one or more components, achieve a technical effect, or otherwise arrive at a desired result.

The logic machine may include one or more processors configured to execute software instructions. Additionally or alternatively, the logic machine may include one or more hardware or firmware logic machines configured to execute hardware or firmware instructions. Processors of the logic machine may be single-core or multi-core, and the instructions executed thereon may be configured for sequential, parallel, and/or distributed processing. Individual components of the logic machine optionally may be distributed among two or more separate devices, which may be remotely located and/or configured for coordinated processing. Aspects of the logic machine may be virtualized and executed by remotely accessible, networked computing devices configured in a cloud-computing configuration.

Storage machine 704 includes one or more physical devices configured to hold instructions 712 executable by the logic machine to implement the methods and processes described herein. When such methods and processes are implemented, the state of storage machine 704 may be transformed—e.g., to hold different data.

Storage machine 704 may include removable and/or built-in devices. Storage machine 704 may include optical memory (e.g., CD, DVD, HD-DVD, Blu-Ray Disc, etc.), semiconductor memory (e.g., RAM, EPROM, EEPROM, etc.), and/or magnetic memory (e.g., hard-disk drive, floppy-disk drive, tape drive, MRAM, etc.), among others. Storage machine 704 may include volatile, nonvolatile, dynamic, static, read/write, read-only, random-access, sequential-access, location-addressable, file-addressable, and/or content-addressable devices.

It will be appreciated that storage machine 704 includes one or more physical devices. However, aspects of the instructions described herein alternatively may be propagated by a communication medium (e.g., an electromagnetic signal, an optical signal, etc.) that is not held by a physical device for a finite duration.

Aspects of logic machine 702 and storage machine 704 may be integrated together into one or more hardware-logic components. Such hardware-logic components may include field-programmable gate arrays (FPGAs), program- and application-specific integrated circuits (PASIC/ASICs), program- and application-specific standard products (PSSP/ASSPs), system-on-a-chip (SOC), and complex programmable logic devices (CPLDs), for example.

When included, display subsystem 706 may be used to present a visual representation of data held by storage machine 704. This visual representation may take the form of a graphical user interface (GUI). As the herein described methods and processes change the data held by the storage machine, and thus transform the state of the storage machine, the state of display subsystem 706 may likewise be transformed to visually represent changes in the underlying data. Display subsystem 706 may include one or more display devices utilizing virtually any type of technology. Such display devices may be combined with logic machine 702 and/or storage machine 704 in a shared enclosure, or such display devices may be peripheral display devices.

When included, input subsystem 708 may comprise or interface with one or more user-input devices such as a keyboard, mouse, or touch screen. In some embodiments, the input subsystem may comprise or interface with selected natural user input (NUI) componentry. Such componentry may be integrated or peripheral, and the transduction and/or processing of input actions may be handled on- or off-board. Example NUI componentry may include a microphone for speech and/or voice recognition, and an infrared, color, stereoscopic, and/or depth camera for machine vision and/or gesture recognition.

When included, communication subsystem 710 may be configured to communicatively couple computing system 700 with one or more other computing devices. Communication subsystem 710 may include wired and/or wireless communication devices compatible with one or more different communication protocols. As non-limiting examples, the communication subsystem may be configured for communication via a wireless telephone network, or a wired or wireless local- or wide-area network. In some embodiments, the communication subsystem may allow computing system 700 to send and/or receive messages to and/or from other devices via a network such as the Internet.

It will be understood that the configurations and/or approaches described herein are exemplary in nature, and that these specific embodiments or examples are not to be considered in a limiting sense, because numerous variations are possible. The specific routines or methods described herein may represent one or more of any number of processing strategies. As such, various acts illustrated and/or described may be performed in the sequence illustrated and/or described, in other sequences, in parallel, or omitted. Likewise, the order of the above-described processes may be changed.

The subject matter of the present disclosure includes all novel and non-obvious combinations and sub-combinations of the various processes, systems and configurations, and other features, functions, acts, and/or properties disclosed herein, as well as any and all equivalents thereof.

1. A method (300) for forming a silicon nitride film on a substrate in a processing chamber by chemical vapor deposition, the method comprising:
introducing (302) a nitrogen-containing precursor into a remote plasma formed in a remote plasma chamber (612) of a processing tool (600);
forming (308) radical nitrogen species in the remote plasma;
flowing (312) an oxygen-free silicon-containing precursor into a processing chamber of the processing tool;
while flowing the oxygen-free silicon-containing precursor, introducing (316) the radical nitrogen species from the remote plasma chamber into the processing chamber; and
reacting (316) the oxygen-free silicon-containing precursor with the radical nitrogen species to form the silicon nitride film on the substrate.

2. The method of claim 1, wherein forming the silicon nitride film comprises forming a conformal silicon nitride film.

3. The method of claim 1, wherein flowing the oxygen-free silicon-containing precursor comprises flowing a silane-based precursor.

4. The method of claim 1, wherein forming the silicon nitride film comprises forming the silicon nitride film on one or more of an amorphous silicon mandrel or an amorphous carbon mandrel.

5. The method of claim 1, wherein forming the silicon nitride film comprises forming the silicon nitride film in one or more gaps on the substrate.

6. The method of claim 1, further comprising performing atomic layer deposition to deposit additional silicon nitride onto the silicon nitride film.

7. The method of claim 1, wherein forming the radical nitrogen species comprises using a radiofrequency power within a range of 300 to 2000 watts to form the remote plasma.

8. The method of claim 1, further comprising controlling a pressure of the processing chamber to within a range of 2 to 8 torr while forming the silicon nitride film.

9. The method of claim 1, wherein introducing the nitrogen-containing precursor into the remote plasma comprises introducing one or more of nitrogen, nitrogen/hydrogen, ammonia, hydrazine, or an amine into the remote plasma.

10. A method of forming a silicon nitride film on a substrate in a processing chamber of a chemical vapor deposition (CVD) tool (600), the method comprising:
introducing (302) a nitrogen-containing precursor into a remote plasma formed in a remote plasma chamber (612) of the CVD tool;
forming (308) radical nitrogen species in the remote plasma;
introducing (312) an oxygen-free silicon-containing precursor into the processing chamber of the CVD tool;
introducing (316) the radical nitrogen species from the remote plasma chamber into the processing chamber;
reacting (316) the oxygen-free silicon-containing precursor with the radical nitrogen species to form the silicon nitride film on the substrate; and
performing (330) atomic layer deposition to form one or more additional layers of silicon nitride on the silicon nitride film.

11. The method of claim 10, wherein forming the silicon nitride film on the substrate comprises forming the silicon nitride film on one or more mandrels.

12. The method of claim 11, wherein the one or more mandrels comprise amorphous silicon.

13. The method of claim 11, wherein the one or more mandrels comprise amorphous carbon.

14. The method of claim 10, wherein forming the silicon nitride film on the substrate comprises forming the silicon nitride film in one or more gaps on the substrate.

15. The method of claim 10, wherein introducing the oxygen-free silicon-containing precursor into the processing chamber comprises introducing a silane-based precursor into the processing chamber.

16. The method of claim 10, wherein introducing the nitrogen-containing precursor into the remote plasma comprises introducing one or more of nitrogen, nitrogen/hydrogen, ammonia, hydrazine, or an amine into the remote plasma.

17. A chemical vapor deposition (CVD) tool (600), comprising:
a processing chamber (602);
a remote plasma chamber (612);
a radiofrequency power source (634) configured to form a plasma in the remote plasma chamber;
a nitrogen precursor source (620) comprising a nitrogen-containing precursor;
an oxygen-free silicon-containing precursor source (624) comprising an oxygen-free silicon-containing precursor;
flow control hardware (614, 616) configured to introduce the nitrogen-containing precursor into the remote plasma chamber and introduce the oxygen-free silicon-containing precursor into the processing chamber; and
a controller (650, 700) configured to
operate the flow control hardware to introduce (302) the nitrogen-containing precursor into the remote plasma chamber;
operate the radiofrequency power source to form (308) a plasma from the nitrogen-containing precursor, the plasma comprising radical nitrogen species,
operate the flow control hardware to flow (312) the oxygen-free silicon-containing precursor into the processing chamber, and
operate the flow control hardware to introduce (316) the radical nitrogen species from the remote plasma chamber into the processing chamber to react with the oxygen-free silicon-containing precursor and form a silicon nitride film on a substrate.

18. The CVD tool of claim 17, wherein the nitrogen-containing precursor source comprises one or more of nitrogen, nitrogen/hydrogen, ammonia, hydrazine, or an amine.

19. The CVD tool of claim 17, further comprising a hydrogen-containing precursor source comprising hydrogen gas, wherein the controller is configured to operate the radiofrequency power source to form the plasma from the nitrogen-containing precursor and the hydrogen gas.

20. The CVD tool of claim 17, further comprising an exhaust system, and wherein the controller is configured to operate the exhaust system and the flow control hardware to generate a pressure within the processing chamber within a range of 2 to 8 torr while forming the silicon nitride film on the substrate.
